(19) United States
(12) Patent Application Publication
(10) Pub. No.: US 2017/0123035 A1
(43) Pub. Date: May 4, 2017

(54) AUTONOMOUS MAGNETOMETER CALIBRATION

(71) Applicant: Kespry, Inc., Menlo Park, CA (US)

(72) Inventor: Robert Parker Clark, Palo Alto, CA (US)

(21) Appl. No.: 14/927,141

(22) Filed: Oct. 29, 2015

(51) Int. Cl. G01R 35/00; G01C 21/20; G01C 21/18; G01R 33/00; B64C 39/02

(52) U.S. Cl. CPC G01R 35/005; G01R 33/0035; B64C 39/024; G01C 21/18; G01C 21/20; B64C 2201/024; B64C 2201/141; B64C 2201/165

(57) ABSTRACT

The disclosure herein describes methods and apparatuses for magnetometer calibration through collection and processing of calibration data in the background and unassisted autonomous calibration maneuvers prior to a mission. As an autonomous or semi-autonomous vehicle is transported by the user after power up, vehicle data relevant to magnetometer calibration can be collected from the movements of the vehicle. Magnetometer calibration accuracy checks or some parts of magnetometer calibration can be performed from the data collected in the background. Based on the extent of accuracy determinations, the vehicle can further perform autonomous and unassisted maneuvers to complete magnetometer calibration before performing a mission.

### BACKGROUND

Field

The described technology generally relates to magnetometer calibration for an autonomous or semi-autonomous vehicle.

Description of the Related Art

An autonomous or semi-autonomous vehicle, such as unmanned aerial vehicle, also commonly referred to as drone, can travel through a variety of environments, such as indoor, outdoor, and/or mixed indoor and outdoor environments. In some cases, an autonomous or semi-autonomous vehicle can be configured to conduct surveillance, security, delivery, monitoring, or other tasks that can comprise combining movement and data collection. As the vehicle travels, it can use magnetic field information at its location using a magnetometer to assist its navigation.

### SUMMARY

The methods and devices of the described technology each have several aspects, no single one of which is solely responsible for its desirable attributes.

In one embodiment, a method for calibrating a magnetometer of an autonomous or semi-autonomous vehicle includes passively collecting magnetometer calibration data prior to initiating a mission of the vehicle, and estimating magnetometer current calibration accuracy based at least in part on the passively collected magnetometer calibration data.

In another embodiment, a method for calibrating a magnetometer of an autonomous or semi-autonomous vehicle includes performing an unassisted magnetometer calibration as part of a pre-mission travel routine, and performing the mission.

In another embodiment, an autonomous or semi-autonomous vehicle includes a magnetometer, a state estimator generating magnetometer calibration data, and memory storing at least part of a pre-mission travel routine for magnetometer calibration.

### BRIEF DESCRIPTION OF THE DRAWINGS

These drawings and the associated description herein are provided to illustrate specific embodiments of the described technology and are not intended to be limiting.

FIG. 1 is an illustration of an example autonomous or semi-autonomous vehicle with reference axes according to one embodiment.

FIG. 2 is a diagram showing an example autonomous or semi-autonomous vehicle according to one embodiment.

FIG. 3 is a flowchart for one stage of passive calibration according to one embodiment.

FIG. 4 is a flowchart for an automatic calibration according to one embodiment.

FIG. 5 is a flowchart for a two-stage automatic calibration according to another embodiment.

FIG. 6 is a flowchart for a part of the automatic calibrations of FIGS. 4 and 5.

### DETAILED DESCRIPTION

Various aspects of the novel systems, apparatuses, and methods are described more fully hereinafter with reference to the accompanying drawings. Aspects of this disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the novel systems, apparatuses, and methods disclosed herein, whether implemented independently of or combined with any other aspect. For example, an apparatus may be implemented or a method may be practiced using any number of the aspects set forth herein. In addition, the scope is intended to encompass apparatus and/or methods which are practiced using structure and/or functionality in addition to or different than the various aspects set forth herein. It should be understood that any aspect disclosed herein might be embodied by one or more elements of a claim.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to different wired and wireless technologies, system configurations, networks, including optical networks, hard disks, and transmission protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

The term “autonomous vehicle” or “semi-autonomous vehicle,” as used herein, generally refers to a vehicle that is configured to operate without substantial or any involvement from an on-board operator (e.g., a driver or pilot). An “unmanned aerial vehicle,” or “UAV,” as used herein, can denote a type of autonomous or semi-autonomous vehicle whose physical operational capabilities include aerial travel or flight. An unmanned aerial vehicle can be an aircraft that is configured to take off and land on a surface. In some cases, an unmanned aerial vehicle can automatically travel from one location to another without any operator involvement. In some cases, an unmanned aerial vehicle can travel a far distance from a starting point. The distance can be far enough that the unmanned aerial vehicle cannot return to a starting point without refueling or recharging at an intermediate location. An unmanned aerial vehicle can be configured to land on a landing pad and/or charge at a charging station.

Magnetometer calibration is a historically cumbersome problem to solve in autonomous or semi-autonomous vehicle travel, such as UAV flight. The magnetic field sensor must be calibrated so that it can determine its orientation relative to Earth's magnetic field even if there are sources of magnetic interference near the magnetometer. These interferences can be complicated and are generally accounted for empirically by gathering data from the sensor and applying a model that is assumed to be true to the resulting data.

The disclosure herein describes methods and apparatus for magnetometer calibration through passive collection and processing of calibration data and unassisted autonomous calibration maneuvers prior to a mission. As an autonomous or semi-autonomous vehicle is transported by the user in preparation for a mission, vehicle data relevant to magnetometer calibration can be collected from the movements of the vehicle. Magnetometer calibration accuracy checks and/or some parts of magnetometer calibration can be performed from the data collected in the background. Based on the accuracy determinations, the vehicle can further perform autonomous and unassisted maneuvers to complete magnetometer calibration before performing a mission.

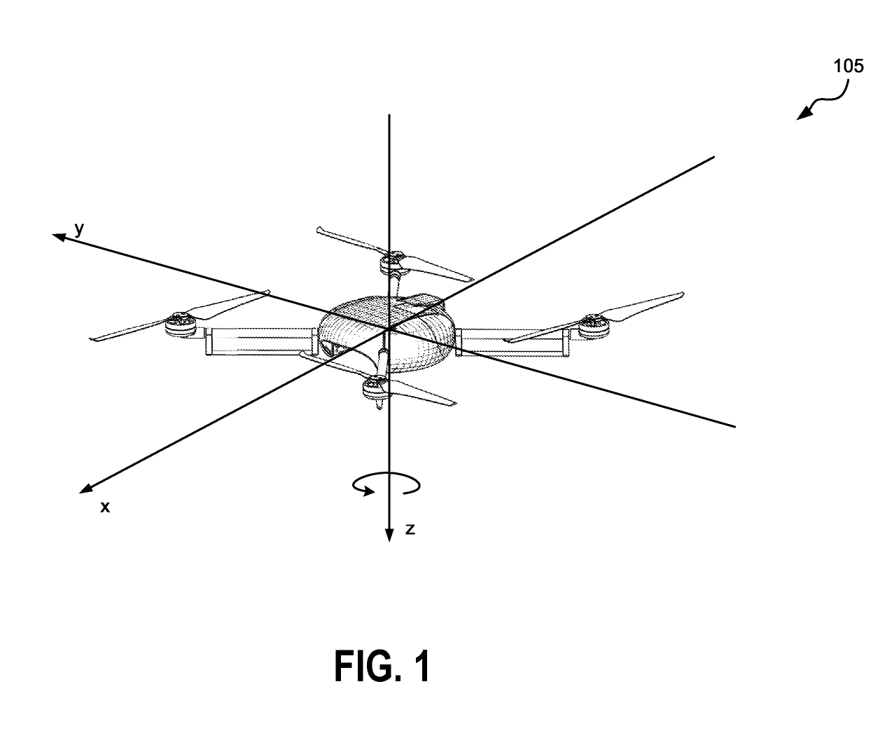

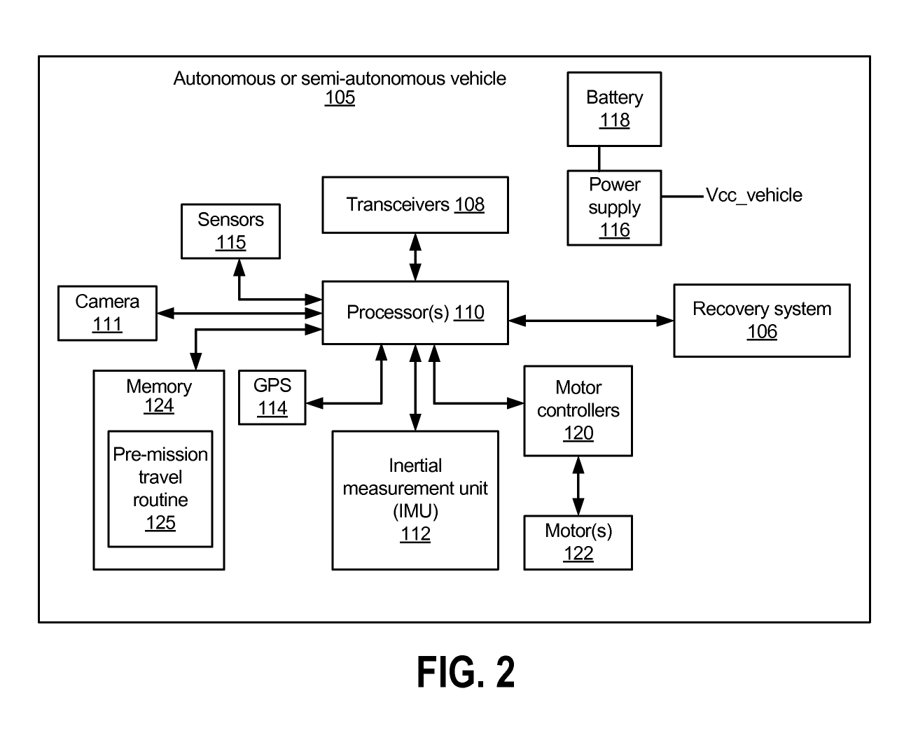

FIG. 1 is an illustration of an example an autonomous or semi-autonomous vehicle with reference axes according to one embodiment. FIG. 1 shows three axes of rotation with the origin at the center of mass of an autonomous or semi-autonomous vehicle 105. As used herein, “roll” generally refers to rotation about the x-axis in FIG. 1; “pitch” generally refers to rotation about the y-axis in FIG. 1; and “yaw” generally refers to rotation about the z-axis in FIG. 1. In some embodiments, one or more sensors or modules of FIG. 2 can be mounted or otherwise configured in accordance with this predetermined set of orientation references (e.g., the x-, y-, and z-axes in FIG. 1) of the vehicle 105, and defining a vehicle reference frame.

In some embodiments, the autonomous or semi-autonomous vehicle 105 can be an unmanned aerial vehicle (UAV), and in other embodiments the vehicle 105 can be a terrestrial or part-terrestrial, part-aerial, and/or amphibious vehicle operating autonomously or semi-autonomously. Although the illustrated vehicle in FIG. 1 is a quadcopter having four arms with their respective rotors, the disclosure herein can be implemented in other types of autonomous or semi-autonomous aerial and/or terrestrial vehicles such as a multirotor helicopter having a different number of arms and/or rotors, an aerial vehicle other than a multirotor helicopter such as a fixed wing aerial vehicle, or other types of vehicles such as cars or walking robots requiring magnetometer calibration updates.

FIG. 2 is a diagram showing components of an example autonomous or semi-autonomous vehicle according to one embodiment. The vehicle 105 illustrated in FIG. 2 includes one or more processor(s) 110 in communication with a state estimator which may be an inertial measurement unit (IMU) 112. The processor 110 is in further communication with one or more transceivers 108, sensors 115, a camera 111, a global positioning system (GPS) module 114, memory 124, and motor controllers 120, which are in communication with motors 122. The vehicle 105 further includes a power supply 116 and a battery 118, which provides power to one or more modules of the vehicle 105, including the processor 110. The transceivers 108 and the GPS module 114 may be in further communication with their respective antennas (not shown). The memory 124 may store a pre-mission travel routine 125, which can be a predetermined operation performed autonomously or without assistance before a mission to calibrate a magnetometer in some embodiments as described herein. The vehicle 105 may also include a recovery system 106, which may be in communication with one or more modules in the vehicle 105, including the processor 110. In some embodiments, the recovery system 106 may include a dedicated recovery processor (not shown) in communication with a recovery state estimator (not shown), which may also be an additional IMU (not shown). The vehicle 105 may include additional or intermediate modules, drivers, controllers, circuitries, lines of communication, and/or signals not illustrated in FIG. 2.

The vehicle 105 can perform its regular operation according to instructions executed by the processor 110 to, for example, take a course of action for a mission. The processor 110 can be a microprocessor capable of communicating with various modules illustrated in FIG. 2 executing instructions pre-programmed and/or received during a mission, for example. The processor 110 may receive settings, values, or parameters stored in the memory 124 and data from the sensors 115, the camera 111, the transceivers 108, the GPS module 114, the IMU 112, and the motor controllers 120 to evaluate the status of the vehicle 105 and determine a course of action. The status of the vehicle 105 can be determined based on data received through the sensors 115 and/or preloaded data stored in the memory 124 and accessed by the processor 110. For example, the altitude of the vehicle 105 above ground can be determined by the processor 108 based on a digital elevation model (DEM) of a world elevation map or with LIDAR, a barometer, GPS, or ultrasound. In some embodiments, the vehicle 105 may include multiple processors of varying levels of computing power and reliability to execute low-level instructions or run high-level application code or a virtual machine. In such embodiments, one or more of the functionalities of the processor(s) 110 described herein may instead be performed by another processor in the vehicle 105.

The transceivers 108 can be devices capable of transmitting and receiving data to and from a system, device, or module external to the vehicle 105. For example, the transceivers 108 may include radio frequency (RF) transceivers capable of communicating data over a Wi-Fi network or any other suitable network in various frequency bands or channels, such as 900 MHz, 2.4 GHz, 5 GHz, etc. In some embodiments, the transceivers 108 may be implemented with a combination of separate transmitters and receivers. The motor controllers 120 may include a controller device or circuit configured to interface between the processor 110 and the motors 122 for regulating and controlling speed, velocity, torque, or other operational parameters of their respective, coupled motors 122. In some embodiments, one or more motor control schemes, such as a feedback control loop, may be implemented with the processor 110 and/or the motor controllers 120. The motors 122 may include electrical or any other suitable motors coupled to their respective rotors of the vehicle 105 to control their propellers, for example.

The recovery system 106 can be responsible for recovery operation of the vehicle 105 to, for example, safely deploy a parachute and land the vehicle 105. The recovery system 106 may include a parachute and an electromechanical deployment mechanism. The power supply 116 may include circuitry such as voltage regulators with outputs directly powering various modules of the vehicle 105 with Vcc_vehicle, and the battery 118 can provide power to the power supply 116. In some embodiments, the battery 118 can be a multi-cell lithium battery or any other suitable battery capable of powering the vehicle 105. In some embodiments, the battery 118 of the vehicle 105 can be removable for easy swapping and charging.

The IMU 112 may include a stand-alone IMU chip containing one or more magnetometers, gyroscopes, accelerometers, and/or barometers. In some embodiments, the IMU 112 may be implemented using a combination of multiple chips or modules configured to perform, for example, measuring of magnetic fields and vehicle orientation and acceleration and to generate related data for further processing with the processor 110. Regardless of integrated or multi-module implementation of the IMU 112, the term “magnetometer” as used herein, generally refers to the part(s) of the IMU 112 responsible for measuring the magnetic field at the location of the vehicle 105. Similarly, the term “accelerometer” as used herein, generally refers to the part(s) of the IMU 112 responsible for measuring acceleration of the vehicle 105, and the term “gyroscope” as used herein, generally refers to the part(s) of the IMU 112 responsible for measuring orientation of the vehicle 105. In some embodiments, the IMU 112 may generate a combined set of data having components corresponding to magnetometer data, accelerometer data, and gyroscope data, and in other embodiments, the magnetometer, accelerometer, and gyroscope of the IMU 112 may respectively generate magnetometer data (e.g., magnetic field strength and/or direction), accelerometer data (e.g., magnitude and/or direction of acceleration), and gyroscope data (e.g., rates of rotation about one or more axes). As used herein, “magnetometer data,” “accelerometer data,” and “gyroscope data” can include direct outputs or raw readings from the respective modules as well as data derived or sourced from the direct outputs of the respective modules.

In some embodiments, the magnetometer of the IMU 112 can be configured to measure a magnetic field at or around the IMU 112 and generate data corresponding to the field strength and/or direction. A typical magnetometer will output a magnetic field magnitude value in three orthogonal directions, and these directions are aligned with the vehicle reference frame axes illustrated in FIG. 1. As discussed further below, the actual measured magnetic field at the IMU will in general differ from the Earth's magnetic field, and calibration factors are used to transform the measured field into an accurate representation of the local Earth's magnetic field.

The sensors 115 may include one or more proximity sensors using, for example, infrared, radar, sonar, ultrasound, LIDAR, barometer, and/or optical technology. The sensors 115 may also include other types of sensors gathering data regarding visual fields, auditory signals, and/or environmental conditions (e.g., temperature, humidity, pressure, etc.). The GPS module 114 may include a GPS transceiver and/or a GPS driver configured to receive raw and/or processed GPS data such as ephemerides for further processing within the GPS module 114, with the processor 110, or both. The vehicle 105 may also include a microphone (not shown) to gather audio data. In some embodiments, one or more sensors 115 responsible for gathering data regarding auditory signals can take the place of the microphone.

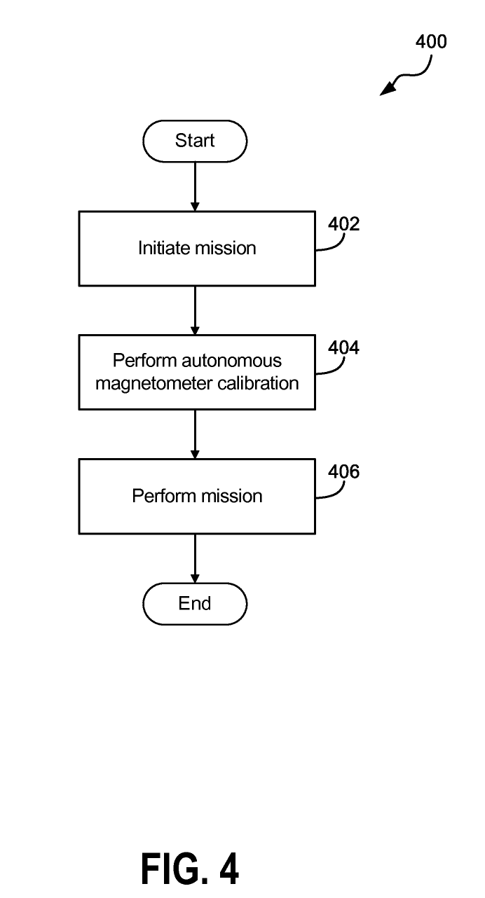

The camera 111 can be configured to gather images and/or video. In some embodiments, one or more sensors 115 responsible for gathering data regarding visual fields can take the place of the camera 111. In some embodiments, the sensors 115 and/or the camera 111 may be configured to gather parts of payload data, which includes data gathered by the vehicle 105 regarding its surroundings, such as images, video, and/or processed 3D mapping data, gathered for purposes of mission performance and/or delivered to the user for various purposes such as surveillance, observation, progress report, landscape analysis, etc. The sensors 115 may also gather what may be termed telemetry data, which is data regarding the status and activities of the vehicle 105 during the flight such as velocity, position, attitude, temperature, and rotor speeds. Such data may be collected to retain records or logs of flight activity and perform diagnostics. In some embodiments, the sensors 115 and/or the camera 111 may also be configured to gather data for purposes of aiding autonomous magnetometer calibration as further discussed in connection with FIGS. 4-6.

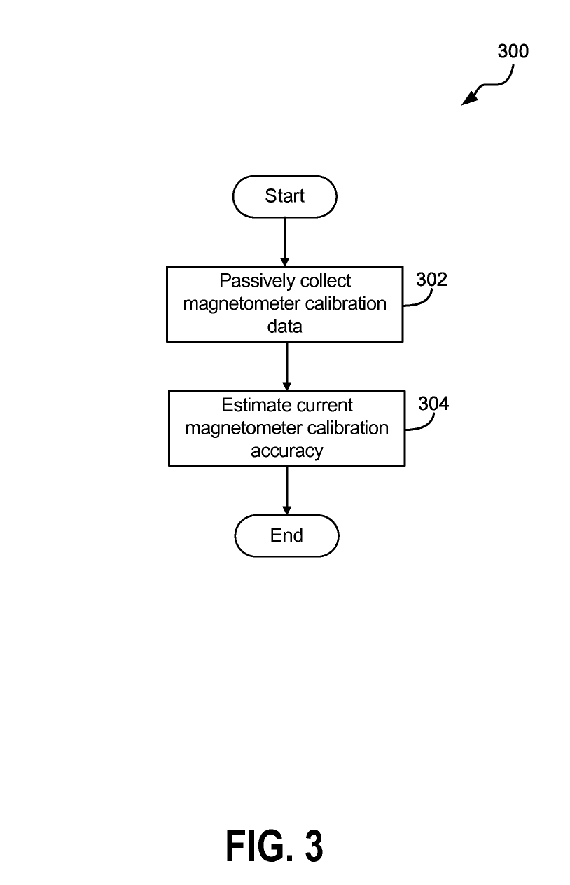

The memory 124 can be a memory storage device (e.g., random-access memory, read-only memory, flash memory, or solid state drive (SSD) storage) to store data collected from the sensors 115, data processed in the processor 110, or preloaded data, parameters, or instructions, which can include the pre-mission travel routine 125. The pre-mission travel routine 125 may include specific travel parameters and/or instructions regarding autonomous magnetometer calibration as described in connection with FIGS. 4-6. In some embodiments, the pre-mission travel routine 125 may include executing a predetermined set of maneuvers for autonomous magnetometer calibration. In other embodiments parts or all of the pre-mission travel routine 125 may be altered or updated for executing an updated set of maneuvers for autonomous magnetometer calibration as the one or more processors 110 may, for example, determine parts of previously executed calibration maneuvers may be unnecessary given a short lapse in time or inappropriate in a changed environment. Further details of the use of the memory 124 and the pre-mission travel routine 125 are discussed in connection with FIGS. 3-6.

A complete magnetometer calibration may involve finding appropriate values of a 3×3 rotation and scaling matrix and a 3×1 bias vector. When applied to a measured magnetic field strength and direction by the magnetometer, the matrix effectively rotates and scales the magnetometer output and the 3×1 bias vector translates the result. Using these two calibration components (one matrix and one vector), one can effectively map the ellipsoid (which is the uncalibrated sensor state) to a spheroid. This calibration procedure is represented mathematically as follows:

$$[ \begin{matrix}{h}_{x} \\ {h}_{y} \\ {h}_{z}\end{matrix} ] = [ \begin{matrix}{c}_{11} & {c}_{12} & {c}_{13} \\ {c}_{21} & {c}_{22} & {c}_{23} \\ {c}_{31} & {c}_{32} & {c}_{33}\end{matrix} ] [ \begin{matrix}{\hat{h}}_{x} \\ {\hat{h}}_{y} \\ {\hat{h}}_{z}\end{matrix} ] - [ \begin{matrix}{b}_{x} \\ {b}_{y } \\ {b}_{z}\end{matrix} ]$$

Where the vector h formed from components hₓ, h_{y}, and h_{z} is the calibrated measurement of the local Earth magnetic field in three orthogonal directions (north-south, east-west, and up-down), the vector ĥ formed from components ĥₓ, ĥ_{y}, and ĥ_{z} are the uncalibrated magnetic field measurements output by the magnetometer. The nine gain matrix entries c and the three bias vector entries b are determined empirically, and may be dependent on inherent properties of the sensor device itself (which may vary from sensor to sensor due to manufacturing or other variations), temperature, humidity, or other environmental factors such as the local presence of magnetized or magnetizable materials. Using a model of sources of errors and interference in magnetometer measurements of the Earth's magnetic field, methods have been devised to derive the gain matrix and bias vector entries that will transform the actual magnetometer output values to accurate measurements of the Earth's magnetic field vector at the magnetometer. An example is provided by Renaudin et al., “Complete Triaxis Magnetometer Calibration in the Magnetic Domain,” Journal of Sensors, Volume 2010, Article ID 967245, which is incorporated by reference herein. Also in another example, the mapping of the uncalibrated sensor state to a calibrated one can be performed by mapping the maxima and minima of the uncalibrated state in the x-, y-, and z-axes to their corresponding maxima and minima of the calibrated state respectively. In this example, the uncalibrated sensor state can be assumed not tilted with respect to the calibrated sensor state, or the tilt may be calibrated out once and then assumed to not vary significantly with time and/or location. In such a case, the most positive x value measured, when multiplied by the gain and added to the bias, should equal the positive horizontal magnetic field magnitude, and the most negative x value measured, when multiplied by the same gain and added to the same bias, should equal the negative horizontal magnetic field magnitude. Similarly, other measured values and their corresponding magnetic field magnitudes can provide equations solvable for one or more of the gain and bias values discussed above (e.g., c₂₂, b_{y}). With this method, the magnetometer output is sampled at a large number of different orientations of the magnetometer. If the magnitude of the local magnetic field is known, which is available from published geomagnetic models for different positions over the Earth's surface, the data points gathered at the different orientations can be used to find appropriate calibration factors for the matrix and vector shown above.

Also, for example, depending on the usual operation of the vehicle 105 or environment in which the vehicle 105 operates, one or more assumptions or simplifications can be made in the magnetometer calibration procedures described herein. For instance, in an embodiment where the vehicle 105 operates mostly horizontally, the vehicle 105 may have significant magnitudes in roll and/or pitch only transiently, or have small, near zero, or zero angles in roll and/or pitch at a time. In such an embodiment, accuracy and magnetometer calibration data regarding the x-axis and y-axis can be more important or significant than data regarding the z-axis. As the vehicle 105 performs the maneuvers (e.g., rotations in yaw) as described herein, the vehicle 105 gathers magnetic field data in x, y, and z. In some implementations, the z-axis components may not be accurately determined as the data gathered regarding the z-axis components can be limited to, for example, to one positive measurement. In such cases, the calibration and updates can be performed on the bias value (e.g., b_{z}) only, assuming the gain value (e.g., c₃₃) is constant. Also as described below in connection with FIG. 3, one or more threshold values can be used to estimate current magnetometer calibration accuracy, and these threshold values can be based on the relative significance of the accuracy and data regarding the different axes. For example, in some embodiments, the threshold for values regarding the x- and y-axes can be a low single digit in percentage from the model (ideal or expected) values while the threshold for values regarding the z-axes can be allowed to vary by up to 10-15% of the model values.

Magnetometer calibration procedures generally begin with a “factory calibration” performed under controlled conditions when the vehicle is first manufactured. During this calibration procedure, a large number of different orientation data points are gathered, environmental conditions such as temperature and humidity may be varied, and all twelve of the above calibration factors, as well as their temperature dependencies and possibly some other environmental dependencies are generated and stored in the memory of the vehicle. This procedure produces an initial set of calibration factors. However, due to changes over time and with local magnetic conditions, these initial values may no longer produce an accurate output. In such embodiments, using the magnetometer to assist navigation may require periodically updating one or more calibration values, such as one or more components of the 3×3 calibration matrix and/or the 3×1 calibration vector. Often, this is done prior to each mission of an autonomous vehicle, conventionally requiring substantial manual user involvement. In contrast, the embodiments described below allow for a highly automated procedure that produces accurate re-calibrations without needing extensive user involvement.

FIG. 3 is a flowchart for one stage of an automatic calibration according to one embodiment. The illustrated process 300 can be performed in part by and/or in conjunction with one or more modules in the vehicle 105 (FIG. 2), such as the processor(s) 110 (FIG. 2), the sensors 115 (FIG. 2), the camera 111 (FIG. 2), the memory 124 (FIG. 2), the GPS module 114 (FIG. 2), and the IMU 112 (FIG. 2). It is to be noted that all or parts of steps 302, and 304 may be concurrently, continuously, periodically, intermittently, repeatedly, or iteratively performed, and the illustrated process in FIG. 3 is only one example of the disclosed herein according to one embodiment. As the vehicle 105 is powered up, the process 300 may start and proceed to step 302.

In step 302, the vehicle 105 passively collects magnetometer calibration data. In some embodiments, as soon as the vehicle 105 is powered on, the vehicle 105 can immediately start collecting magnetometer calibration data regardless of whether a mission instruction is received. “Passively collecting” or “passive collection,” as described herein, generally refers to collecting of data during movements of the vehicle 105 without proactive or intentional intervention by the user for purposes of calibration. For example, after powering on the vehicle 105, the user may move the vehicle 105 from one location to another in preparation for sending the vehicle 105 on a mission from the latter location. As the vehicle 105 is moved, the velocity, position, and orientation of the vehicle 105 may change accordingly, and such changes present an opportunity to gather corresponding data (e.g., acceleration data, gyroscope data, GPS data, magnetometer data) that can be used for one or both of evaluating the accuracy of the current magnetometer calibration factors and adjusting one or more of those values in accordance with the requirements of the current environment. As disclosed herein, it can be advantageous to make use of movements of the vehicle 105 unrelated to calibration by allowing passive collection of data as the passively collected data can provide data points for checking and updating magnetometer calibration. Generally speaking, data from other sensors such as an accelerometer and/or gyroscope can be compared to output data from the magnetometer to see if the outputs are consistent with each other. If they are, this indicates that the magnetometer calibration factors currently being used are still accurate. Inconsistency indicates otherwise.

Passive collection of magnetometer calibration data can be implemented at various ways. In some embodiments, passive calibration data collection can be hardwired in the vehicle 105 system so that as soon as the necessary modules (e.g., the IMU 112, the processor 110) are powered on, they can start generating and collecting data by default. In some embodiments, instructions for passively collecting magnetometer calibration data can be stored in the memory 124 (e.g., ROM) to be automatically executed. In other embodiments, passive data collection may be part of an initialization routine of a higher-level instruction executed by the processor 110. In some embodiments, the vehicle 105 can be configured to concurrently or subsequently perform pre-travel checks and other logic checks while the passive collection of calibration data is performed.

In step 304 accuracy of current magnetometer calibration can be estimated. In some embodiments, non-magnetometer data and magnetometer data can be compared to determine the accuracy of current magnetometer calibration. For example, magnetometer data can include the magnitude of the calibrated magnetometer output (e.g. the square root of the sum of the squares of hₓ, h_{y}, and h_{z} above) and non-magnetometer data can be a fetched or preloaded value for the Earth's known magnetic field magnitude at the geographical location of the vehicle 105. Using the GPS information from the GPS module 114, the location of the vehicle 105 can be determined, and the corresponding Earth's magnetic field magnitude can be obtained from, for example, a lookup table stored in the memory 124. If the magnetic field magnitude from the calibrated magnetometer data and the known Earth's magnetic field magnitude differ by greater than an acceptable threshold, it can be indicated in step 304 that the current magnetometer calibration (e.g., one or more components of the calibration matrix and the calibration vector) may not be accurate. In addition, the magnitude of the calibrated magnetometer output should not change as the orientation of the vehicle changes. If this magnitude is dependent on vehicle orientation, then the current calibration factors may be inaccurate.

In another example, magnetometer data can include an estimate of the orientation of the vehicle 105 based on the calibrated magnetometer outputs as the corresponding magnetometer predicted orientation can be derived from a magnetometer reading (e.g., magnetic field magnitude and direction) using quaternion multiplication. The orientation of the vehicle 105 can also be estimated from non-magnetometer data such as data from the accelerometer and/or gyroscope. By comparing the magnetometer data indicating supposed orientation of the vehicle 105 and the non-magnetometer data indicating orientation of the vehicle 105, the accuracy of current magnetometer calibration can be determined. If the difference in the orientation information from the magnetometer and non-magnetometer data is not within an acceptable threshold, the current calibration of the magnetometer is not accurate.

In another example, magnetometer data can include the rate of yaw change during vehicle movements computed from the magnetometer readings, and non-magnetometer data can include rate of yaw change during the same vehicle movements simultaneously measured and computed from the gyroscope. By comparing the magnetometer data and the non-magnetometer data regarding the rate of yaw change and determining whether the difference exceeds an acceptable threshold, the accuracy of current magnetometer calibration can be determined.

In some embodiments, acceptable thresholds for the magnetic field magnitude at the location of the vehicle 105, the orientation of the vehicle 105, and the rate of yaw change of the vehicle 105 can be predetermined and stored in the memory 124. In some embodiments, the acceptable thresholds can be determined in part empirically and the thresholds are often greater than zero as the sensors and modules inherently produce noise. For example, an acceptable threshold can be a low single digit percentage variance from a model as discussed above in connection with FIG. 2. In other embodiments, one or more acceptable thresholds can be updated dynamically or determined on an ad-hoc basis.

In some embodiments, some components of the calibration matrix or the calibration vector can be disregarded or assumed since some components may wholly or largely represent invariable hardware qualities and sometimes estimated or degenerate models can be sufficiently adequate in certain implementations or situations. For example, it can generally be assumed that the non-diagonal elements of the calibration matrix depend only on the sensor, are sufficiently determined during the factory calibration procedure, and need not be re-calibrated in the field later. Furthermore, values for c₃₃ and b_{z} can also be held fixed to their factory calibration values since they only affect the z-component of the output, which is of lesser significance in navigation as discussed above in connection with FIG. 2.

In some embodiments steps 302 and 304 can be repeatedly performed in a loop as the passive collection of data by its unintentional nature can produce more or less data that necessary to fully determine calibration accuracy depending on the movement of the vehicle 105. In instances where the passively collected data are insufficient to fully determine the accuracy of the magnetometer calibration accuracy, parts of the magnetometer calibration accuracy can be determined or confirmed during the process 300.

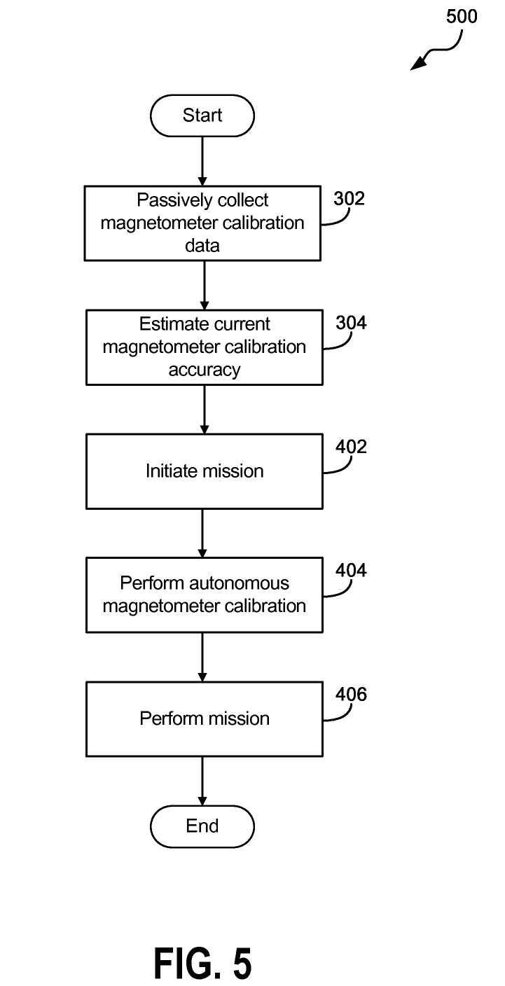

In some embodiments, with sufficient amount of passively collected data, in addition to determining magnetometer calibration accuracy with the process 300, magnetometer calibration parameters can be updated, thereby completing magnetometer calibration following the process 300. For example, if the movement of the vehicle 105 unrelated to calibration by the user is sufficient enough (e.g., amounting to 270 degrees of accumulated rotation about the z-axis of FIG. 1 when the calibration factors c₁₁, c₂₂, b₁, and b₂ are being determined), the passively collected data during this movement can be enough to perform a magnetometer calibration by updating the magnetometer calibration parameters after the process 300 in an additional optional step, using, for example, techniques similar to those described in the Renaudin paper mentioned above with a plurality of data points of magnetometer data gathered passively during movement of the vehicle by the user prior to a mission. As further discussed in connection with FIG. 5, even when magnetometer calibration cannot be performed due to insufficient passively collected data, to the extent that the process 300 is performed, additional steps to complete magnetometer calibration can be reduced. Conversely, to the extent that the vehicle 105 is configured to perform certain parts of magnetometer calibration maneuvers or routines described below (e.g., confirmatory rotation in step 608), parts of the process 300 can be omitted to balance between the desired accuracy of magnetometer calibration and unnecessary redundancy in various steps in calibrating the magnetometer.

FIG. 4 is a flowchart for another stage of an automatic calibration according to another embodiment. The illustrated process 400 can be performed in part by and/or in conjunction with one or more modules in the vehicle 105 (FIG. 2), such as the processor(s) 110 (FIG. 2), the sensors 115 (FIG. 2), the camera 111 (FIG. 2), the memory 124 (FIG. 2), the GPS module 114 (FIG. 2), the IMU 112 (FIG. 2), and the motor controllers 120 (FIG. 2). It is to be noted that all or parts of steps 402, 404, and 406 may be concurrently, continuously, periodically, intermittently, repeatedly, or iteratively performed, and the illustrated process in FIG. 4 is only one example of the disclosed herein according to one embodiment. As the vehicle 105 is powered up, the process 400 may proceed to step 402.

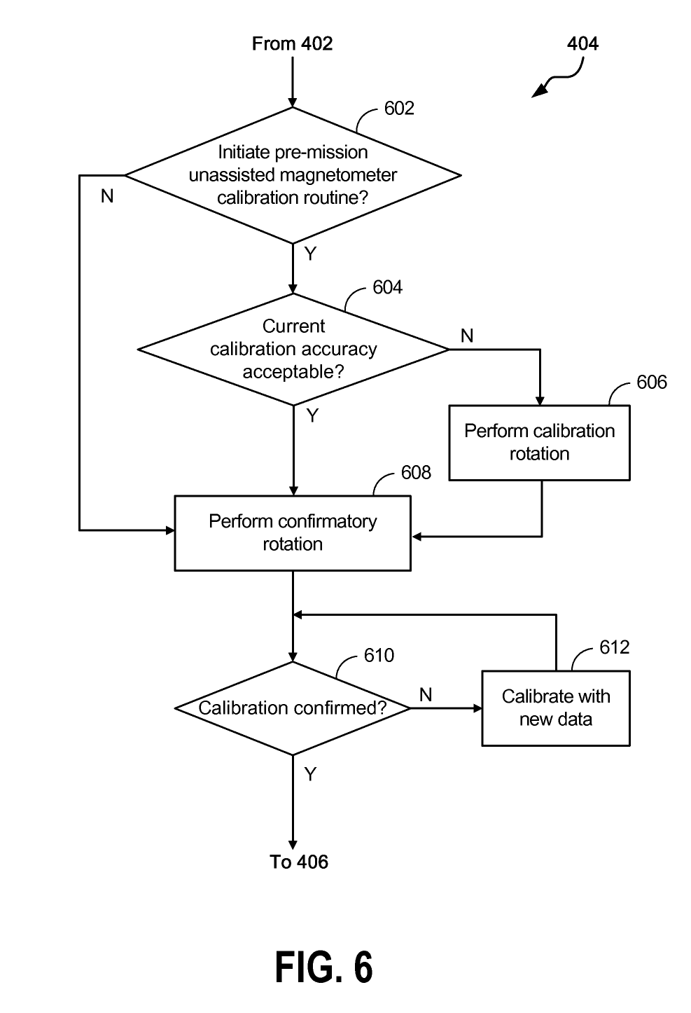

In step 402, the vehicle 105 receives and initiates a mission to perform. In some embodiments, once the vehicle 105 is powered up, the processor 110 may perform preflight checks or other logic checks to allow the initiation of the mission. In some embodiments, step 404 discussed below may automatically be performed upon initiation of a mission. In other embodiments, whether and to what extent to proceed to step 404 can be determined based on various factors as further discussed in connection with FIG. 6 below.

In step 404, autonomous magnetometer calibration can be performed. As further described in connection with FIG. 6 below, step 404 may comprise a plurality of sub-processes or steps, some of which (e.g., steps 604, 606) can be optional or omitted. In some embodiments, autonomous magnetometer calibration can be based on previously collected data and/or the most recent determination of calibration accuracy, if any. Depending on the level of current calibration data accuracy, status, and information, the vehicle 105 can be configured to autonomously perform one or more maneuvers without the user's assistance to calibrate the magnetometer. Magnetometer data collected during these maneuvers can be used to determine calibration factors using, for example, techniques similar to those described in the Renaudin paper mentioned above with a plurality of data points of magnetometer data gathered during the maneuvers. The maneuvers can be designed to place the vehicle in the various orientations desired for gathering magnetometer data for calibration purposes. As used herein, “unassisted magnetometer calibration” or “autonomous magnetometer calibration,” generally refers to magnetometer calibration achieved by the vehicle 105 though one or more autonomous maneuvers without any assistance or specific directions from the user. In some embodiments, the vehicle 105 may use the sensors 115 or the camera 111 to aid the autonomous magnetometer calibration. In some embodiments, the instructions for the autonomous magnetometer calibration can be stored as the pre-mission travel routine 124 in the memory 124 ready to be executed by default upon initiation of the mission. In other embodiments, the pre-mission travel routine 124 can be modified, or extra determinations can be made prior for the vehicle 105 to perform the autonomous magnetometer calibration. Further details of one implementation of step 404 are discussed in connection with FIG. 6 below.

In step 406, the vehicle 105 performs the mission upon completion of the autonomous magnetometer calibration in step 404. The autonomous magnetometer calibration as described herein can be advantageous as the vehicle 105 can proceed with steps 402, 404, and 406 upon power up and receipt of a mission without the user's invention to calibrate the magnetometer of the vehicle. As the autonomous magnetometer calibration described herein does not rely on the user's deliberate intervention to calibrate the magnetometer, errors or inaccuracies resulting from the user's various placements of the vehicle 105 can be alleviated.

FIG. 5 is a flowchart for a two-stage automatic calibration according to another embodiment. The two-stage automatic calibration process 500 can be a combination of the processes 300 (FIG. 3) and 400 (FIG. 4) in a manner same or substantially similar to the steps discussed above in connection with FIGS. 3 and 4. In some embodiments, it can be advantageous to combine the steps from FIGS. 3 and 4 because in the combined process 500, the processes 300 and 400 can complement each other so that to the extent the accuracy of the magnetometer calibration is determined during steps 302 and 304, at least parts of steps 402, 404, and 406 can be curtailed or omitted, conserving power and calibration time.

FIG. 6 is a flowchart for a part of the automatic calibrations of FIGS. 4 and 5. The flowchart in FIG. 6 illustrates step 404 discussed above in connection with FIGS. 4 and 5 in further detail. It is to be noted that all or parts of steps 602, 604, 606, and 608 may be concurrently, continuously, periodically, intermittently, repeatedly, or iteratively performed, and the illustrated process in FIG. 6 is only one example. In some embodiments, the pre-mission travel routine 125 (FIG. 2) stored in the memory 124 can include instructions corresponding to at least parts of the steps in FIG. 6.

In step 602, whether the pre-mission unassisted calibration should be performed is determined. In some embodiments, step 602 can be implemented so that the autonomous calibration routine (steps 604, 606, and/or 608) is always performed upon initiation of a mission. In some embodiments, at least parts of the autonomous calibration routine (e.g., step 608) can always be performed after the mission is initiated as illustrated in the example process in FIG. 6. For example, if the vehicle 105 collects enough calibration data during steps 302, 304 (FIG. 5) so that the vehicle 105 can calibrate its magnetometer with only passively collected data, the vehicle 105 may determine that unassisted magnetometer calibration routine in step 602 is not necessary. In such instance, the process 404 may proceed to step 608 to confirm calibration. In other embodiments, depending on the most recent time, location, or other relevant conditions of magnetometer calibration, the vehicle 105 with its processor(s) 110 can determine that confirming or updating magnetometer calibration through the pre-mission calibration routine is not necessary and proceed to perform the mission. For example, performing a pre-mission magnetometer calibration routine as described in steps 604, 606, 608 before every mission may not be necessary or can even be wasteful for repeated short missions at a geographically confined location over a short period of time. In such case, parts of FIG. 6 can be omitted and/or replaced with short confirmatory checks from already collected data without deliberate calibration maneuvers.

In step 604, whether the current magnetometer calibration accuracy is acceptable is determined. In embodiments implementing the process 400, the vehicle 105 may not have previously collected calibration related data or made any determination as to the accuracy of magnetometer calibration. In such case, it can be assumed that the calibration accuracy is not acceptable, and the process can proceed to step 606. In embodiments implementing the process 500, the vehicle may have passively collected magnetometer calibration data and may also have determined whether the current calibration is accurate as discussed in connection with FIGS. 4-5 above. If it has already been determined that the current magnetometer calibration is accurate, the process proceeds to step 608. If it has determined that the magnetometer calibration is inaccurate or that the accuracy is inconclusive or unknown, the process proceeds to step 606.

In step 606, the vehicle 105 performs an autonomous rotation for calibration. As described herein, “rotation” generally refers to a change in angle about one or more of the three axes of rotation of the vehicle 105 discussed above in connection with FIG. 1. Outside the context of passive data collection and “accumulated rotation” described in connection with FIGS. 3-5 above, “rotation” as in “autonomous calibration rotation” and “confirmatory rotation” refers to a controlled change in angle, which is deliberately controlled by one or more of the processors 110 (FIG. 2) of the vehicle 105. The change in angle during a “rotation” generally refers to a change in angle that is calibration significant, which means more than a de minimis degree (e.g., noise, jitter) but may be less than a full 360 degree rotation. In some embodiments, the vehicle 105 can be configured to disregard magnetometer data pertaining to absolute yaw of the vehicle 105 while it performs the autonomous calibration rotation, which can be a rotation approximately about the z-axis (e.g., as shown in FIG. 1, making movements in yaw) to a sufficient degree (e.g., 270 degrees or more in z-axis). In other embodiments, the autonomous calibration rotation may also include some rotation(s) about one or both of the x- and y-axes, which can provide additional calibration data.

In some embodiments, the vehicle 105 can hover close to the ground as it performs the autonomous calibration rotation, for example, at a fall-safe distance from the ground. In other embodiments, the vehicle 105 may perform the autonomous calibration rotation at a sufficient altitude above ground that reduces or minimizes ground-level magnetic field distortions, such as disruptions or distortions caused by below-ground pipes, electric cables, or ores. The distance from the ground, for example, can be determined by one or more of the sensors 115 (e.g., ultrasound, LIDAR, barometer, optical sensor). In some embodiments, data regarding potential near ground disturbances at certain geographical locations can be stored in, sent to, or retrieved by the vehicle 105 using one or more modules illustrated in FIG. 2 above. Also in some embodiments, the vehicle 105 can be preprogrammed to perform the autonomous calibration at a certain altitude while in other embodiments, the vehicle 105 may be configured to at least in part determine at what altitude to perform the autonomous calibration rotation based on gathered sensor data and/or retrieved or stored data. In some embodiments, at a given location, the vehicle 105 may determine the altitude at which to perform the autonomous calibration rotation, adjust calibration computation to account for distortions, or both. For example, the vehicle 105 may determine the near-ground magnetic field distortions are too great and unaccountable (e.g., random or unpredictable), and the vehicle 105 may perform the autonomous calibration at an altitude where the near-ground magnetic field distortions are negligible. In another instance, if the near-ground magnetic field distortions are negligible or can be easily accounted for in calibration computation, the vehicle 105 may determine to perform the autonomous calibration at a fall-safe altitude from ground. In another instance, the vehicle 105 may do both by performing at a fall-safe altitude and at a higher than fall-safe altitude and account for small or predictable distortions during calibration computation.

In some embodiments, data from the GPS module can be used to determine the position of the vehicle 105. In some embodiments, the camera 111 and the processor 110 can obtain and process images (e.g., optical flow) to estimate relative position of the vehicle 105 since acquiring GPS data can initially be delayed. Also in some embodiments, data from the accelerometer and the gyroscope can be used for attitude estimation and position of the vehicle 105 while the vehicle 105 performs the autonomous calibration rotation, for example, approximately about the z-axis. As the vehicle 105 performs the autonomous calibration rotation to a sufficient degree (e.g., 270 degrees or more in z-axis), the uncalibrated, or assumed to be uncalibrated, magnetometer data can be gathered, and in conjunction with data gathered or preprogramed (e.g., GPS location of the vehicle 105, Earth's magnetic field and direction at the location, near-ground magnetic field distortion), one or more components of the calibration matrix and vector (e.g., matrix gains or x, y diagonal entries, bias components or x, y components of the calibration vector) can be determined by, for example, the processor(s) 110. In some instances, some components of the calibration matrix and vector can be estimated to further improve magnetometer calibration. As the vehicle 105 performs the calibration rotation and the one or more components of the calibration matrix and vector are determined, magnetometer calibration values or parameters can be updated according to the determined component values so that the uncalibrated sensor state (e.g., skewed and/or offset ellipsoid) is mapped to a calibrated sensor state (e.g., centered spheroid) as described above in connection with FIG. 2. Once the calibration rotation is performed and the magnetometer calibration update is completed, the process proceeds to step 608.

In step 608, the vehicle 105 performs an autonomous rotation for calibration confirmation as the magnetometer at this stage is already or assumed to have been calibrated. In some embodiments, the vehicle 105 can take off and hover a few meters off the ground, and a confirmatory rotation approximately about the z-axis can be performed. Similar to the features described in connection with step 606, the vehicle 105 may determine and/or adjust at what altitude the vehicle 105 should perform the confirmatory rotation as suitable depending on, for example, absence or presence of near-ground magnetic field distortion.

In step 610, the vehicle 105 can determine and confirm the accuracy of the magnetometer calibration by comparing magnetometer data and non-magnetometer data similar to the process described in connection with step 304 (FIG. 3) above. The vehicle 105, for example, may determine that the newly gathered calibration data from the confirmatory rotation in step 608 fits the existing calibration, thus confirming the current magnetometer calibration is accurate. If the accuracy of the magnetometer calibration is confirmed in step 610, the vehicle 105 can proceed to step 406 to perform the mission as instructed. If the accuracy of the magnetometer calibration is not confirmed, the process 404 may proceed to step 612 to update magnetometer calibration.

In step 612, the vehicle 105 may calibrate the magnetometer using the calibration data gathered during step 608. In some embodiments, upon applying the new or most recent calibration data, the process 404 may proceed to step 610 to determine if the calibration accuracy can be confirmed. In other embodiments, after step 612, the process may proceed to step 608 to perform another confirmatory rotation 608 to gather another set of calibration data, especially in case the vehicle 105 has determined in step 610 that the calibration accuracy was significantly low or inaccurate. In other embodiments, the vehicle 105 may calibrate the magnetometer in step 612 using the most recent calibration data and proceed to step 406 to perform a mission assuming that the calibration based on the most recent calibration data is accurate. In some embodiments, one or more of the steps described above following step 612 can be performed repeatedly or in a loop to reach a desired level of magnetometer accuracy. Also, in some embodiments, upon one or more attempts at performing parts of the automated calibration rotation(s) (e.g., step 608), calibration(s) with the most recent data (e.g., step 612), and accuracy determination(s) and confirmation(s) (e.g., step 610), the vehicle 105 may be configured to safely land and/or indicate calibration error. For example, the vehicle 105 may be configured to repeat the autonomous calibration rotations for no more than a set number of times or abort the mission, and the vehicle 105 may indicate calibration error, for instance, through generating lights, sounds, and/or error messages to one or more devices in communication with the vehicle 105.

The foregoing description and claims may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the Figures depict example arrangements of elements and components, additional intervening elements, devices, features, or components may be present in an actual embodiment (assuming that the functionality of the depicted circuits is not adversely affected).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The various operations of methods described above may be performed by any suitable means capable of performing the operations, such as various hardware and/or software component(s), circuits, and/or module(s). Generally, any operations illustrated in the Figures may be performed by corresponding functional means capable of performing the operations.

The various illustrative logical blocks, modules, and circuits described in connection with the present disclosure may be implemented or performed with a general purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. A general-purpose processor may be a microprocessor, but in the alternative, the processor may be any commercially available processor, controller, microcontroller or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the implementations are not limited to the precise configuration and components illustrated above. Various modifications, changes and variations may be made in the arrangement, operation and details of the methods and apparatus described above without departing from the scope of the implementations.

Although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well.

What is claimed is:

1. A method for calibrating a magnetometer of an autonomous or semi-autonomous vehicle comprising:
passively collecting magnetometer calibration data prior to initiating a mission of the vehicle; and
estimating current magnetometer calibration accuracy based at least in part on the passively collected magnetometer calibration data.

2. The method of claim 1 further comprising:
initiating the mission;
performing an autonomous magnetometer calibration based at least in part on the estimated calibration accuracy; and
performing the mission.

3. The method of claim 1 further comprising:
determining whether to perform an autonomous magnetometer calibration based at least in part on the time of most recent magnetometer calibration; and
performing the autonomous magnetometer calibration based at least in part on the estimated calibration accuracy.

4. The method of claim 1, wherein the collected magnetometer calibration data comprises at least one of:
magnetic field data;
global positioning system (GPS) data;
accelerometer data; and
gyroscope data.

5. The method of claim 1, further comprising updating one or more calibration values based in part on the collected magnetometer calibration data.

6. The method of claim 5, wherein the one or more calibration values comprise one or more entries of a calibration matrix.

7. The method of claim 1, wherein the estimating current magnetometer calibration accuracy comprises at least one of:
determining measured magnetic field accuracy based on the passively collected magnetometer calibration data; and
determining measured orientation accuracy based on the passively collected magnetometer calibration data.

8. The method of claim 7, wherein the determining measured magnetic field accuracy comprises:
determining the current geolocation of the vehicle;
obtaining an expected magnetic field magnitude at the current geolocation;
determining a field magnitude measurement based in part on the collected magnetometer calibration data; and
comparing the field magnitude measurement with the expected magnetic field magnitude.

9. The method of claim 7, wherein the determining orientation accuracy further comprises:
determining a first orientation computation based on accelerometer and gyroscope data;
determining a second orientation computation based on magnetometer data;
comparing the first and second orientation computations.

10. The method of claim 1, wherein the autonomous magnetometer calibration comprises:
initiating the flight of the vehicle;
hovering the vehicle;
rotating the vehicle about a vertical axis; and
updating a calibration setting.

11. The method of claim 10, wherein the vehicle rotates for at least 270 degrees about the vertical axis.

12. The method of claim 10, wherein the magnetometer calibration further comprises:
re-rotating the vehicle about the vertical axis; and
updating the calibration setting.

13. A method for calibrating a magnetometer of an autonomous or semi-autonomous vehicle comprising:
performing an unassisted magnetometer calibration as part of a pre-mission travel routine; and
performing the mission.

14. The method of claim 13, wherein performing the unassisted calibration of the vehicle comprising:
determining current magnetometer calibration accuracy of the vehicle;
performing a calibration rotation about a vertical axis if the current calibration accuracy is outside an acceptable range; and
performing a confirmatory rotation about the vertical axis.

15. The method of claim 14, wherein the calibration rotation is performed at a safe-drop distance from ground.

16. The method of claim 14 further comprising updating a calibration setting of the vehicle at least in part during the calibration rotation.

17. The method of claim 14, wherein performing the calibration rotation is based in part on an altitude estimation of the unmanned vehicle.

18. The method of claim 17, wherein the altitude estimation is based in part at least one of:
image data;
proximity sensor data;
barometer data; and
LIDAR.

19. The method of claim 14, wherein completing the confirmatory rotation is based in part on global positioning system (GPS) data of the vehicle.

20. An autonomous or semi-autonomous vehicle comprising:
a magnetometer; and
memory storing at least part of a pre-mission travel routine for magnetometer calibration.

21. The vehicle of claim 20 further comprising one or more processors, at least one of which being configured to:
collect magnetometer data prior to initiating a mission;
estimate magnetometer calibration accuracy based in part on the collected magnetometer data; and
perform the pre-mission travel routine for magnetometer calibration based in part on the magnetometer calibration accuracy.

22. The vehicle of claim 21 further comprising at least one of:
an accelerometer; and
a gyroscope,
wherein the accelerometer and/or the gyroscope generate(s) calibration data,
wherein the one or more processors estimate the magnetometer calibration accuracy by comparing the generated calibration data with the collected magnetometer data.

23. The vehicle of claim 20, wherein the at least one of the one or more processors is further configured to:
initiate the mission;
hover the vehicle;
rotate the vehicle about a vertical axis; and
update a calibration setting.
